(19) United States
(12) Patent Application Publication
(10) Pub. No.: US 2025/0283921 A1
(43) Pub. Date: Sep. 11, 2025

(54) A TEMPERATURE STABLE OPTICAL POCKELS ELECTRIC FIELD SENSOR AND METHODS THEREOF

(71) Applicant: MICATU, INC., Horseheads, NY (US)

(72) Inventors: Michael OSHETSKI, Horseheads, NY (US); James KENNEDY, Corning, NY (US); Atul PRADHAN, Pittsford, NY (US)

(21) Appl. No.: 18/861,448

(22) PCT Filed: Apr. 25, 2023
(86) PCT No.: PCT/US2023/066158

§ 371 Date: Oct. 29, 2024

Related U.S. Application Data
(60) Provisional application No. 63/338,223, filed on May 4, 2022.

(51) Int. Cl. G01R 15/24; G01R 29/08

(52) U.S. Cl. CPC G01R 15/242; G01R 15/247; G01R 29/0885

(57) ABSTRACT

The disclosed technology relates to optical electric field sensor devices with improved thermal stability that leverage the Pockels effect to detect electric fields using rubidium titanyl phosphate (RbTiOPO4) (RTP) crystal(s). An exemplary optical electric field sensor device includes an input collimator configured to collimate an input light beam from a light source. The optical electric field sensor device further includes a crystal material positioned to receive the input light beam via the input collimator, configured to exhibit the Pockels effect when an electric field is applied through the crystal material, and comprising RTP. The optical electric field sensor device further includes an output collimator configured to focus an output light beam received from the crystal material onto at least one detector.

This application claims priority to U.S. Provisional Patent Application No. 63/338,223, filed May 4, 2022, which is incorporated by reference herein in its entirety.

### FIELD

The disclosed technology relates to optical sensors and, more particularly, to high precision optical sensors based on the Pockels effect for detecting and measuring electric fields.

### BACKGROUND

The ability to detect electric fields is important in a number of industries. For example, in the utility industry, detection of electric fields is necessary to measure voltage potential and current. In addition to measurement of electrical properties, detection of electric fields is important in industrial deployments in which ensuring that systems are de-energized is critical for safety. In these environments, it is not important that absolute values of electric field (e.g., voltage) be measured, only that their presence be accurately detected.

Electric field detection is of primary importance in the electrical utility industry, where voltages and currents must be monitored at generation source, on transmission grids, on distribution grids, and at final electrical circuits. Detecting and measuring electric fields at these locations is paramount to ensuring that electricity is transmitted through the electrical grid to end users at the correct voltage. In addition to measuring electric fields for the delivery of electricity, there is a need within the utility industry to detect electric fields during inclement climatic and meteorological conditions. In such conditions, the environmental or air temperature can vary greatly.

Historically, measurement of medium voltage at distribution substations has been accomplished using iron-core ferro-magnetic voltage transformers. Such technologies, however, inherently disturb the Electromagnetic Field (EMF) associated with medium voltage transmission measurement and actively interfere with the voltage to be determined, thereby indirectly compromising the voltage measurement. These conventional measurement devices also have associated risks and danger due to arcing, flash, magnetic saturation, explosions, and catastrophic failure, among others.

In view of the challenges inherent in electromagnetic voltage measurement technology, optical sensors have been proposed for medium and high-voltage environments, as well as for low-voltage applications. Such sensors are immune to electromagnetic and radio frequency interference, with no inductive coupling or galvanic connection between the sensor head on high-voltage lines and power transmission substation electronics. The wide bandwidth of optical sensors provides for fast fault and transient detection and power quality monitoring and protection. Optical sensors can be easily installed on, or integrated into, existing substation infrastructure and equipment such as circuit breakers, insulators, or bushings resulting in significant space saving and reduced installation costs with no environmental impact.

Optical voltage sensors that utilize the Pockels effect, which is also referred to as the linear electro-optic effect, and include a polarizer at the input and a beam splitter at the output, have been developed. These devices have been deployed by a number of utilities and found to function well at constant temperature. However, when exposed to significant temperature, humidity, and/or environmental weather swings, these devices are no longer able to accurately monitor voltage. Thus, a major issue in the reliability of current optical voltage sensors is environmental stability, particularly sensitivity due to temperature and humidity of the ambient environment surrounding the optical system or assembly.

In some current optical voltage sensors, elaborate polarization diversity schemes have been employed that involve various optical components dedicated to polarization manipulation of phase and rotation. However, such polarization components, such as wave plates, retarders, and beam splitters are fragile and can vary greatly over temperature and environmental condition ranges that can change the phase of the optical beam and resultant signal.

In one particular example of such devices, an electro-optical voltage sensor comprised of double, or stacked, lithium niobate (LiNbO3) crystals with a complex air spaced polarization diversity scheme showed improved stability from 0 degrees centigrade to +50 degrees centigrade, but did not meet the temperature stability requirements necessary for monitoring medium and high voltage transmission lines, which require stability from −40 degrees centigrade to +80 degrees centigrade. Thus, there is a need in the art for an optical voltage sensor capable of maintaining accurate readings over increased temperature ranges.

### SUMMARY

In one example, an optical electric field sensor device is disclosed that includes an input collimator configured to collimate an input light beam from a light source. The optical electric field sensor device in this example further includes a crystal material positioned to receive the input light beam via the input collimator, configured to exhibit the Pockels effect when an electric field is applied through the crystal material, and comprising rubidium titanyl phosphate (RbTiOPO4) (RTP). The optical electric field sensor device in this example also includes an output collimator configured to focus an output light beam received from the crystal material onto at least one detector.

In another example, an optical electric field sensor device is disclosed that includes a first input collimator, a first crystal material, and a first output collimator collectively comprising a first independent light path through the optical electric field sensor. The first input collimator is configured to collimate an input light beam from a light source. The first crystal material is positioned to receive the input light beam via the first input collimator, is configured to exhibit the Pockels effect when an electric field is applied through the first crystal material, and comprises RTP. The first output collimator is configured to focus a first output light beam received from the first crystal material onto a detector.

The optical electric field sensor in this example further includes a second input collimator, a second crystal material, and a second output collimator collectively comprising a second independent light path through the optical electric field sensor. The second input collimator is configured to collimate a second input light beam from the light source. The second crystal material is positioned to receive the second input light beam via the second input collimator, is configured to exhibit the Pockels effect when the electric field is applied through the second crystal material, and comprises RTP. The second output collimator is configured to focus a second output light beam received from the second crystal material onto the detector.

The technology described and illustrated herein includes an optical electric field sensor based on the Pockels effect that provides improved thermal stability. The optical electric field sensor includes a single continuous optical beam path from light source to photodiode through the optical electric field sensor components.

The components of the optical electric field sensor disclosed herein advantageously include RTP crystal(s) to produce a relatively stable temperature sensor capable of measuring voltage based on the optical Pockels effect. The RTP crystals are aligned with respect to the X-cut or Y-cut planes defining the optical axis and direction of light propagation, but the axes perpendicular to the optical axis, or direction of light propagation, are clocked or rotated by π/4 radians or 90 degrees with respect to each other.

Accordingly, this technology provides a light-weight, temperature insensitive, and repeatable device for detecting electric fields that can be easily deployed in many industrial and utility applications. Due to the disclosed optical electric field sensor being athermal, it offers enhanced performance in inclement temperature and climatic environments minimizing the risk of erroneous voltage readings due to temperature variations in utility grid systems, for example.

### BRIEF DESCRIPTION OF THE DRAWINGS

FIG. 1 is a conceptual optical diagram of light propagation in an exemplary optical electric field sensor;

FIG. 2 is a perspective view of an exemplary optical electric field sensor;

FIG. 3A is a graph of the Pockels effect modulation in Volts for a single crystal lithium niobate (LiNbO3) optical electric field sensor; and

FIG. 3B is a graph of the Pockels effect modulation in Volts for a dual crystal RTP optical electric field sensor.

### DETAILED DESCRIPTION

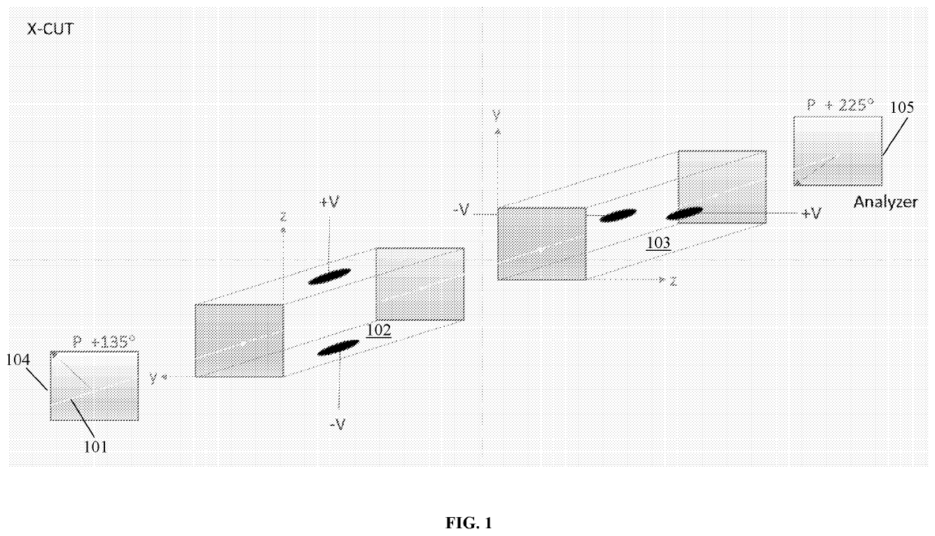

Referring to FIG. 1, a conceptual optical diagram of an exemplary optical electric field sensor assembly is illustrated. In this example, the path of a light ray 101 is shown as being through a first crystal 102 and a second crystal 103 along with an input polarizer 104 before the first crystal 102 and an output polarizer 105 after the second crystal 103. Also illustrated in FIG. 1 are voltage drops due to the electric field permeating the Pockels effect x-cut first and second crystals 102 and 103, respectively. Thus, FIG. 1 illustrates the polarization and crystal axis orientations relative to the light ray 101 propagation through the first and second crystals 102 and 103, respectively.

The direction of light propagation corresponds to the x axis in this example, which is also the axis of each of the first and second crystals 102 and 103, respectively. Without loss of generality, a corresponding approach can be implemented with y-cut crystals, and other types of crystals with other axes can also be used in other examples. The input polarization, as set by the input polarizer 104, and output polarization, as analyzed at the output polarizer 105, are also shown in FIG. 1 with their orientation relative to the crystal axes. In some examples, the input polarizer 104 and/or output polarizer 105 can be polarizing collimators (i.e., polarizers coupled to collimator lenses), as described and illustrated in U.S. Pat. No. 10,175,425, which is incorporated by reference herein in its entirety, although other types of polarizers can also be used in other examples.

In this example, the light ray 101 is perpendicular and incident to the faces defined by the cut orientation of the first and second crystals 102 and 103, respectively, and parallel to the axes of the first and second crystals 102 and 103, respectively. The first crystal 102 is shown such that an electric field permeates the first crystal 102 thereby generating a voltage difference between opposing surfaces of the first crystal 102 in the z-direction given by V=Ed, where E is the average magnitude of the electric field, and d is the thickness between opposing surfaces.

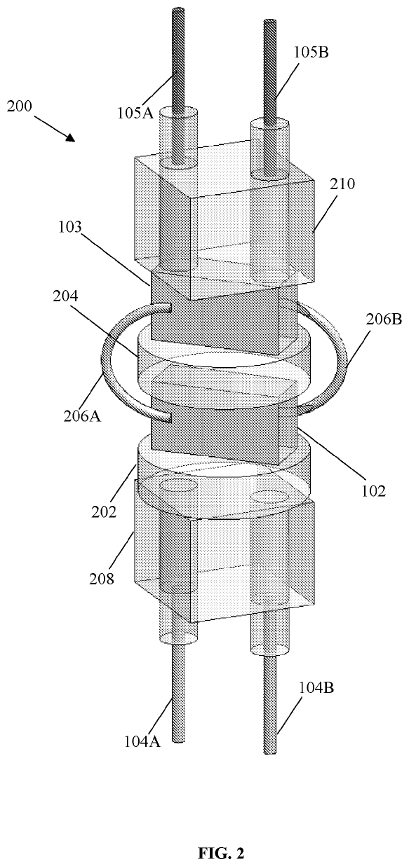

The second crystal 103 in this example is clocked or rotated at 90 degrees (i.e., π/4 radians) relative to the first crystal 102. The opposing surfaces of the second crystal 103 along its z-axis are constrained to have the same potential or voltage difference as the first crystal 102, by means of wired or trace electrical connections to the first crystal 102, as described and illustrated in more detail below with reference to FIG. 2.

The first crystal 102 is oriented such that its axis is in the direction of propagation of light and the extraordinary (e) and ordinary (o) refractive index axes (z and x in this particular example) are oriented at right angles with respect to the axis of the first crystal 102. The second crystal 103 is oriented such that its axis is aligned to that of the first crystal 102, but its e and o axes are perpendicular to the corresponding axes of the first crystal 102 and are rotated by 90 degrees (i.e.,π/4 radians) with respect to those of the first crystal 102. Thus, incident light is polarized by the input polarizer 104 such that the initial polarization vector is at π/4 radians or 45 degrees to the perpendicular e and o axes of the second crystal 103, and will exhibit an optical amplitude phase shift due to the Pockels effect with the second crystal 103 sensing the electric field across its opposing surfaces.

The temperature dependence of the Pockels effect in the first and second crystals 102 and 103, respectively, is substantially linear. However, it can be obscured by birefringence in the first and second crystals 102 and 103, respectively, due to coefficient of thermal expansions (CTE) induced changes and associated temperature dependent stress. The technology described and illustrated by way of the examples herein advantageously substantially eliminates the temperature dependent birefringence.

In particular, the birefringence component of the phase shift in the second crystal 103 substantially cancels that due to first crystal 102 because the respective axes of each of the first and second crystals 102 and 103, respectively, are clocked. The resultant light exiting the second crystal 103 can be analyzed by the output polarizer 105 such that the light intensity on a receiving photodiode will have a modulation that is dependent on the electric field due to the Pockels effect with birefringence effects or contributions greatly reduced or eliminated.

As shown in FIG. 1, the input polarizer 104 is oriented at 45 degrees with respect to either the e or o axes of the first crystal 102. In one example, a quarter wave plate (QWP) retarder may optionally be added between the input polarizer 104 and the first crystal 102, with an axis aligned 45 degrees (π/4 radians) to the e or o axis of the first crystal 102, as described and illustrated in more detail below with reference to FIG. 2. The purpose of the QWP is to facilitate ease of adjustment and fine tuning of the polarization. However, the basic functionality of the technology disclosed herein does not necessitate inclusion of the QWP.

In another example, a half wave plate (HWP) retarder may optionally be added between the first crystal 102 and the second crystal 103 with an axis aligned to either the e or o axes of either of the first or second crystal 102 or 103, respectively. The use of the HWP would obviate the need to physically clock the first and second crystals 102 and 103, respectively, with respect to each other since the light ray 101 polarization would be physically rotated by 90 degrees (π/4 radians) to be in the proper orientation when incident on the second crystal 103 with projections along the e and o axes of the second crystal 103 such that the accumulation of the Pockels effect phase is additive and the birefringence phase is subtractive. This combination of phases from the first and second crystals 102 and 103, respectively, will now be described.

The differential optical phase of light through the direction of propagation is given by polarization projection upon the e and o axes of the respective one of the first and second crystals 102 and 103, respectively, and in general is given by Γ=β+ϕ, where β is the birefringence phase and ϕ is the Pockels effect phase. For an x-cut crystal (e.g., the first crystal 102), the birefringence is given by β_{First}=k(n_{y}−n_{z})L, where n_{y} and n_{z} are the refractive indices of light polarized along the respective axes, L is the length of the crystal in terms of light optical path, k is 2π/λ, and λ is wavelength of the light.

In the examples described and illustrated herein, the first and second crystals 102 and 103, respectively, advantageously comprise rubidium titanyl phosphate (RbTiOPO₄) (RTP). Thus, the Pockels effect phase in the first crystal 102 is given by

$${ϕ}_{First} = k \frac{( {n}_{z}^{3} {r}_{33} - {n}_{y}^{3} {r}_{23} )}{{n}_{z}^{3}} \frac{V L}{2 d} ,$$

where r₃₃ and r₂₃ are Pockels effect tensor coefficients for RTP, V is the voltage magnitude in a bi-polar drop across the first and second crystals 102 and 103, respectively, and d is the potential drop distance of electric field, or the thickness of the first crystal 102 along the E-field direction.

For the second crystal 103, similarly, the birefringence is given by β_{Second}=k(n_{z}−n_{y})L, with the change in sign due to the clocking of the second crystal 103 relative to the first crystal 102. The Pockels effect phase also is similar:

$${ϕ}_{S e c o n d} = k \frac{( {n}_{z}^{3} {r}_{33} - {n}_{y}^{3} {r}_{23} )}{{n}_{z}^{3}} \frac{V L}{2 d} .$$

Thus, the total combined optical phase for both the first and second crystals 102 and 103, respectively, is Γ=β_{First}+ϕ_{First}+β_{Second}+ϕ_{Second}. Therefore, Γ=ϕ_{First}+ϕ_{Second}, and the birefringence terms β_{First} and β_{Second} advantageously cancel.

Accordingly, the light ray 101 along the direction of propagation has an optical phase amplitude given by

$$Γ = k \frac{( {n}_{z}^{3} {r}_{33} - {n}_{y}^{3} {r}_{23} )}{{n}_{z}^{3}} \frac{V L}{d} .$$

If the half wave voltage is defined as

$${V}_{π} = \frac{{n}_{z}^{3}}{( {n}_{z}^{3} {r}_{33} - {n}_{y}^{3} {r}_{23} )} \frac{d λ}{2 L} ,$$

the optical phase can be expressed as Γ=πV(t)/V_{π}. Here, the Pockels effect phase is dependent on the time varying voltage V(t), which is the object of measurement. The output polarizer 105 in this example is configured to resolve and superpose polarization components exhibiting differential optical phase, thereby producing light with an optical phase amplitude that will exhibit a time varying optical intensity modulation, which can be detected on a receiving photodiode, as will now be explained in more detail with reference to FIG. 2.

In FIG. 2, a perspective view of an exemplary optical electric field sensor 200 is illustrated. In this particular example, two independent light path channels are used to provide redundancy for improved operational performance, although only one light path channel, or more than two independent light path channels, can also be used in other examples. The exemplary optical electric field sensor 200 includes a first crystal 102 and a second crystal 103, each of which is made at least in part of RTP material. The crystal structure is orthorhombic, with point group mm2, which contributes to minimal piezo-electric resonances and ringing, although other structures can also be used.

The optical electric field sensor 200 in this example further includes a QWP 202 that facilitates granular tuning of the input polarization, a HWP 204 that rotates the polarization between the first and second crystals 102 and 103, respectively, and wiring or electrical traces 206A-B that connect the same opposing surfaces in both the first and second crystals 102 and 103, respectively, to ensure uniform and consistent voltage difference between the opposing surfaces. Accordingly, the electrical traces 206A-B ensure consistent voltage for both the first and second crystal 102 and 103, respectively, according to the electric field direction.

The optical electric field sensor 200 in this example also includes a first input polarizer 104A and second input polarizer 104B (e.g., polarizing collimators as explained above with reference to FIG. 1), each of which is embedded in a first collimator block 208. The first and second input polarizers 104A-B are followed in each respective light path channel by optical components as described above, namely the QWP 202, first crystal 102, HWP 204, second crystal 103, a first output polarizer 105A, and a second output polarizer 105B. Each of the first and second output polarizers 105A and 105B, respectively, is also embedded in a second collimator block 210 in this example.

The expression for the optical transmission through the optical electric field sensor 200 to the Pockels effect phase can be represented as the square of the optical phase amplitude. The optical modulation intensity or power due to the electric field, as measured by the optical electric field sensor 200, can thus be determined as a function of the applied voltage across the first and second crystals 102 and 103, respectively.

In some examples, the optical electric field sensor 200 is configured to be electrically and communicably coupled to a sensor computing device comprising a processor coupled to a memory and configured to execute instructions stored in the memory to obtain and process an output from each of the output analyzers 105A-B and/or one or more detectors (e.g., photodiodes) coupled thereto. In particular, the output can be averaged to improve accuracy. In another example, redundancy can be provided, and results can be discarded, if one light path channel yields values that exceed predefined thresholds, for example.

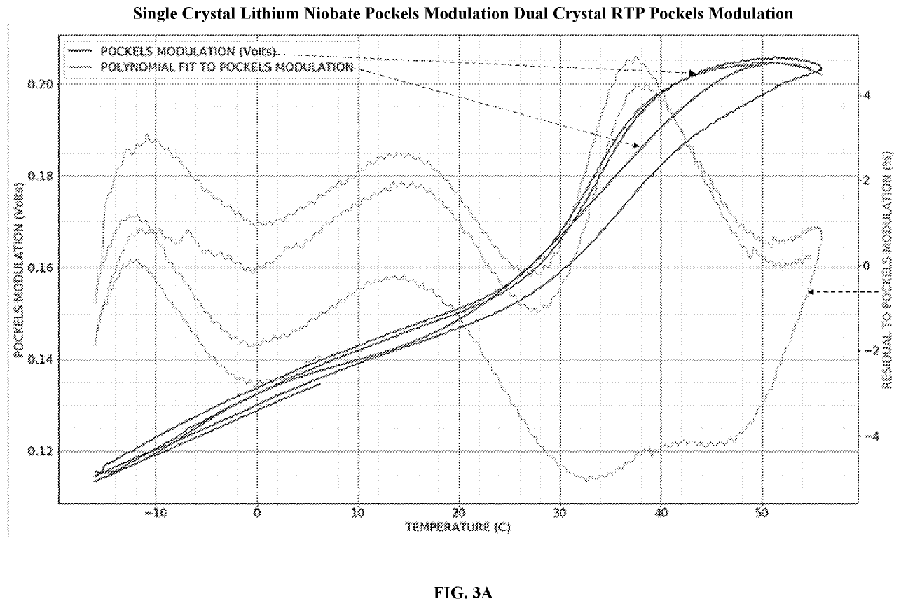

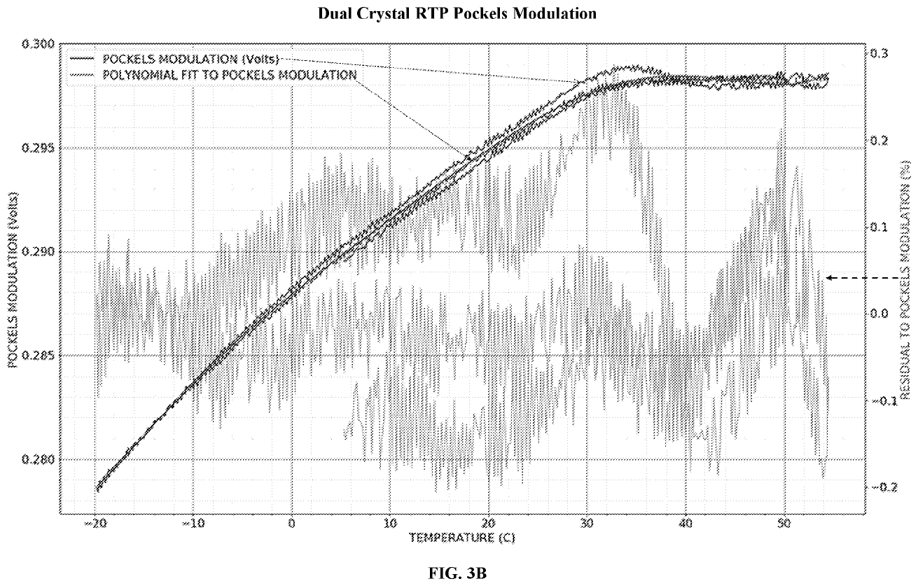

Referring to FIG. 3, a graph of the magnitude of modulated optical power intensity at a receive photodiode that is plotted versus both temperature and time for the exemplary optical electric field sensor 200 is illustrated, along with a comparison with corresponding data from a single crystal lithium niobate (LiNbO3) optical electric field sensor, such as disclosed in U.S. Patent Application Publication No. 2020/0241053, which is incorporated by reference herein in its entirety.

Referring to FIG. 3A, the Pockels effect modulation in Volts for a single crystal lithium niobate (LiNbO3) optical electric field sensor with a polynomial fit overlayed is illustrated. The single crystal lithium niobate (LiNbO3) optical electric field sensor used is as disclosed in U.S. Patent Application Publication No. 2020/0241053. The residual is also shown on the right axis and represents the sum of squares associated with the mean standard error expressed in percentage terms.

Referring to FIG. 3B, the Pockels effect modulation in Volts for a dual crystal RTP optical electric field sensor 200, such as described and illustrated herein with reference to FIG. 2. The salient observation is that the temperature dependent fit is significantly and non-negligibly improved as shown in the residual error being less by as much as an order of magnitude or more for the dual crystal RTP optical electric field sensor 200 versus a single crystal lithium niobate (LiNbO3) optical electric field sensor.

With the technology described and illustrated by way of the examples herein, an optical electric field sensor 200 is provided with improved thermal stability and more accurate detection of electric fields in a wider range of temperature and environment conditions. This technology reduces the risk of erroneous voltage readings and due to temperature variations in utility electrical grid systems and other types of deployments.

Having thus described the basic concept of the invention, it will be rather apparent to those skilled in the art that the foregoing detailed disclosure is intended to be presented by way of example only, and is not limiting. Various alterations, improvements, and modifications will occur and are intended to those skilled in the art, though not expressly stated herein. These alterations, improvements, and modifications are intended to be suggested hereby, and are within the spirit and scope of the invention. Additionally, the recited order of processing elements or sequences, or the use of numbers, letters, or other designations therefore, is not intended to limit the claimed processes to any order except as may be specified in the claims. Accordingly, the invention is limited only by the following claims and equivalents thereto.

What is claimed is:

1. An optical electric field sensor, comprising:
a first input collimator configured to collimate a first input light beam from a light source;
a first crystal material positioned to receive the first input light beam via the first input collimator, configured to exhibit the Pockels effect when an electric field is applied through the first crystal material, and comprising rubidium titanyl phosphate (RbTiOPO4) (RTP); and
a first output collimator configured to focus a first output light beam received from the first crystal material onto at least one detector.

2. The optical electric field sensor of claim 1, wherein the first input collimator, the first crystal material, and the first output collimator collectively comprise a first independent light path through the optical field electric sensor and the optical field electric sensor further comprises:
a second input collimator, a second crystal material, and a second output collimator collectively comprising a second independent light path through the optical electric field sensor, wherein:
the second input collimator is configured to collimate a second input light beam from the light source;
the second crystal material is positioned to receive the second input light beam via the second input collimator, is configured to exhibit the Pockels effect when another electric field is applied through the second crystal material, and comprises RTP; and
the second output collimator is configured to focus a second output light beam received from the second crystal material onto the at least one detector.

3. The optical electric field sensor of claim 2, further comprising first and second electrical traces each in contact with a corresponding opposing surface of each of the first crystal material and the second crystal material.

4. The optical electric field sensor of claim 2, further comprising:
first and second input polarizers configured to polarize the first and second input light beams, respectively; and
first and second output polarizers configured to polarize the first and second output light beams, respectively.

5. The optical electric field sensor of claim 2, further comprising:
a first collimator block into which the first and second input collimators are embedded; and
a second collimator block into which the first and second output collimators are embedded.

6. The optical electric field sensor of claim 2, further comprising a half wave plate positioned between the first crystal material and the second crystal material and having an axis aligned to the e or o axes of the first crystal material or the second crystal material.

7. The optical electric field sensor of claim 2, wherein the second crystal material is clocked at 90 degrees relative to the first crystal material.

8. The optical electric field sensor of claim 1, further comprising a quarter wave plate positioned between the first input collimator and the first crystal material and having an axis aligned 45 degrees to the e or o axis of the first crystal material.

9. An optical electric field sensor, comprising:
a first input collimator, a first crystal material, and a first output collimator collectively comprising a first independent light path through the optical electric field sensor, wherein:
the first input collimator is configured to collimate an input light beam from a light source;
the first crystal material is positioned to receive the input light beam via the first input collimator, is configured to exhibit the Pockels effect when an electric field is applied through the first crystal material, and comprises rubidium titanyl phosphate (RbTiOPO4) (RTP); and
the first output collimator is configured to focus a first output light beam received from the first crystal material onto a detector; and
a second input collimator, a second crystal material, and a second output collimator collectively comprising a second independent light path through the optical electric field sensor, wherein:
the second input collimator is configured to collimate a second input light beam from the light source;
the second crystal material is positioned to receive the second input light beam via the second input collimator, is configured to exhibit the Pockels effect when the electric field is applied through the second crystal material, and comprises RTP; and
the second output collimator is configured to focus a second output light beam received from the second crystal material onto the detector.

10. The optical electric field sensor of claim 9, further comprising first and second electrical traces each in contact with a corresponding opposing surface of each of the first crystal material and the second crystal material.

11. The optical electric field sensor of claim 9, further comprising:
first and second input polarizers configured to polarize the first and second input light beams, respectively; and
first and second output polarizers configured to polarize the first and second output light beams, respectively.

12. The optical electric field sensor of claim 9, further comprising:
a first collimator block into which the first and second input collimators are embedded; and
a second collimator block into which the first and second output collimators are embedded.

13. The optical electric field sensor of claim 9, further comprising a half wave plate positioned between the first crystal material and the second crystal material and having an axis aligned to the e or o axes of the first crystal material or the second crystal material.

14. The optical electric field sensor of claim 9, wherein the second crystal material is clocked at 90 degrees relative to the first crystal material.

15. The optical electric field sensor of claim 9, further comprising a quarter wave plate positioned between the first and second input collimators and the first crystal material and having an axis aligned 45 degrees to the e or o axis of the first crystal material.
